(19) United States
(12) Patent Application Publication
(10) Pub. No.: US 2025/0256692 A1
(43) Pub. Date: Aug. 14, 2025

(54) HYDRAULIC PRESSURE CONTROL UNIT

(71) Applicant: Robert Bosch GmbH, Stuttgart (DE)

(72) Inventor: Yuki Ikeda, Kanagawa (JP)

(21) Appl. No.: 18/260,258

(22) PCT Filed: Dec. 21, 2021
(86) PCT No.: PCT/IB2021/062088

§ 371 Date: Jun. 4, 2024

(30) Foreign Application Priority Data
Jan. 7, 2021 (JP) 2021-001170

(51) Int. Cl. B60T 8/32; B60T 13/68; B60T 17/22

(52) U.S. Cl. CPC B60T 8/3225; B60T 13/686; B60T 17/22; B60T 2270/88

(57) ABSTRACT

The present invention obtains a hydraulic pressure control unit capable of accurately evaluating viscosity of a hydraulic fluid.

The hydraulic pressure control unit according to the present invention includes a controller including an evaluation section that evaluates the viscosity of the hydraulic fluid. The evaluation section evaluates the viscosity on the basis of a reduced amount of a current value of a current flowing through a wire (314) at a time when the current value is temporarily reduced in a process in which the current value is increased toward a target current value at beginning of application of the current to the wire (314) of an electromagnetic valve (31).

### BACKGROUND

The present disclosure relates to a hydraulic pressure control unit capable of accurately evaluating viscosity of a hydraulic fluid.

Conventionally, as a behavior control system for controlling behavior of a vehicle such as a motorcycle, there is a system using a hydraulic pressure control unit that controls a hydraulic pressure generated in a hydraulic fluid. In the hydraulic pressure control unit, the hydraulic pressure that is generated in the hydraulic fluid is controlled by operating an electromagnetic valve that is provided to a channel for the hydraulic fluid.

Here, when viscosity of the hydraulic fluid is increased, movement of an armature that is a movable portion in the electromagnetic valve tends to be restricted. Thus, in the case where the viscosity of the hydraulic fluid is excessively high, there is a possibility that a function of the electromagnetic valve to open/close the channel is not exerted appropriately. In order to handle such a problem, a technique of evaluating the viscosity of the hydraulic fluid has been proposed to comprehend an actuation state of the electromagnetic valve (for example, see JP2019215009A).

By the way, the viscosity of the hydraulic fluid is changed as the hydraulic fluid is deteriorated. For example, the viscosity of the hydraulic fluid is increased as the hydraulic fluid is deteriorated and water content of the hydraulic fluid is increased. However, in the related art of the hydraulic pressure control unit, the change in the viscosity associated with the deterioration of the hydraulic fluid is not taken into account in the evaluation of the viscosity of the hydraulic fluid, and the viscosity of the hydraulic fluid is not evaluated accurate enough.

### SUMMARY

The present invention has been made with the above-described problem as the background and therefore obtains a hydraulic pressure control unit capable of accurately evaluating viscosity of a hydraulic fluid.

A hydraulic pressure control unit according to the present invention is a hydraulic pressure control unit used for a behavior control system of a vehicle, and includes: a hydraulic pressure control mechanism that includes a base body and components including an electromagnetic valve assembled to the base body for controlling a hydraulic pressure generated in a hydraulic fluid for the behavior control system; and a controller that includes a control section controlling operation of the components. The electromagnetic valve includes a wire and an armature that moves in association with application of a current to the wire, and is a valve that is closed or a valve that is opened in an energized state where the current is applied to the wire. The controller includes an evaluation section that evaluates viscosity of the hydraulic fluid. The evaluation section evaluates the viscosity on the basis of a reduced amount of a current value of the current flowing through the wire at a time when the current value is temporarily reduced in a process in which the current value is increased toward a target current value at beginning of the application of the current to the wire.

In the hydraulic pressure control unit according to the present invention, the controller includes the evaluation section that evaluates the viscosity of the hydraulic fluid. The evaluation section evaluates the viscosity on the basis of the reduced amount of the current value of the current flowing through the wire at the time when the current value is temporarily reduced in the process in which the current value is increased toward the target current value at the beginning of the application of the current to the wire of the electromagnetic valve. In this way, it is possible to evaluate the viscosity of the hydraulic fluid by taking a change in the viscosity associated with the deterioration of the hydraulic fluid into account. Therefore, it is possible to accurately evaluate the viscosity of the hydraulic fluid.

### BRIEF DESCRIPTION OF DRAWINGS

FIG. 1 is a schematic view illustrating an outline configuration of a vehicle according to an embodiment of the present invention.

FIG. 2 is a schematic view illustrating an outline configuration of a brake system according to the embodiment of the present invention.

FIG. 3 is a schematic cross-sectional view illustrating an example of an electromagnetic valve in a hydraulic pressure control unit according to the embodiment of the present invention.

FIG. 4 is a schematic view illustrating an example of a current sensor in the hydraulic pressure control unit according to the embodiment of the present invention.

FIG. 5 is a block diagram illustrating an example of a functional configuration of a controller according to the embodiment of the present invention.

FIG. 6 is a schematic graph illustrating an example of transition of a current value of a current flowing through a wire at beginning of application of the current to the wire of the electromagnetic valve in the hydraulic pressure control unit according to the embodiment of the present invention.

FIG. 7 is a flowchart illustrating an example of a processing procedure related to evaluation of viscosity of a hydraulic fluid that is executed by the controller according to the embodiment of the present invention.

### DETAILED DESCRIPTION

A description will hereinafter be made on a hydraulic pressure control unit according to the present invention with reference to the drawings.

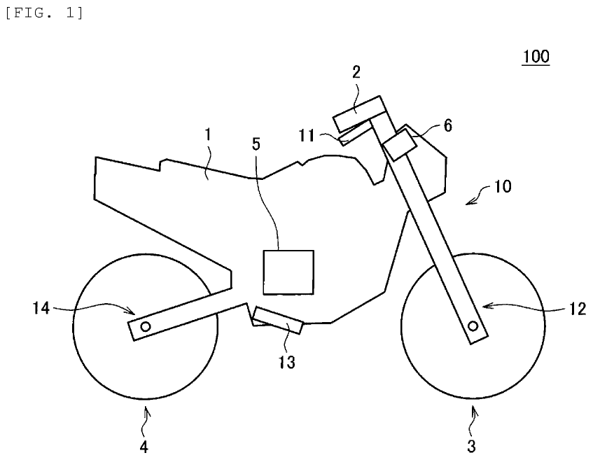

A description will hereinafter be made on the hydraulic pressure control unit that is used for a brake system of a two-wheeled motorcycle (see a vehicle 100 in FIG. 1). However, the hydraulic pressure control unit according to the present invention may be used for a behavior control system other than the brake system (for example, a system that controls a damping force of a suspension, or the like). In addition, the hydraulic pressure control unit according to the present invention may be used for the behavior control system of a vehicle other than the two-wheeled motorcycle (for example, another straddle-type vehicle, such as an all-terrain vehicle, a three-wheeled motorcycle, or a bicycle, a four-wheeled automobile, or the like). Here, the straddle-type vehicle means a vehicle that a rider straddles, and includes a scooter and the like.

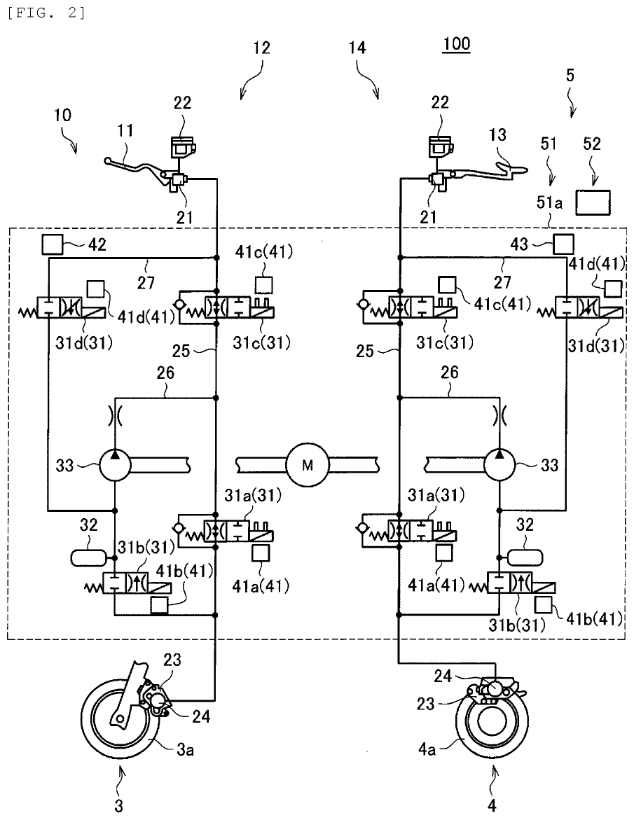

A description will hereinafter be made on a case where one front-wheel brake mechanism and one rear-wheel brake mechanism are provided (see a front-wheel brake mechanism 12 and a rear-wheel brake mechanism 14 in FIG. 2). However, at least one of the front-wheel brake mechanism and the rear-wheel brake mechanism may be plural. Alternatively, one of the front-wheel brake mechanism and the rear-wheel brake mechanism may not be provided.

A configuration, operation, and the like, which will be described below, constitute merely one example, and the hydraulic pressure control unit according to the present invention is not limited to a case with such a configuration, such operation, and the like.

The same or similar description will appropriately be simplified or will not be made below. In the drawings, the same or similar members or portions will not be denoted by a reference sign or will be denoted by the same reference sign. A detailed structure will appropriately be illustrated in a simplified manner or will not be illustrated.

### Vehicle Configuration

A description will be made on a configuration of the vehicle 100 according to an embodiment of the present invention with reference to FIG. 1 to FIG. 5.

FIG. 1 is a schematic view illustrating an outline configuration of the vehicle 100. FIG. 2 is a schematic view illustrating an outline configuration of a brake system 10.

The vehicle 100 is a two-wheeled motorcycle that corresponds to an example of the vehicle according to the present invention. As illustrated in FIG. 1, the vehicle 100 includes: a trunk 1; a handlebar 2 that is held by the trunk 1 in a freely turnable manner; a front wheel 3 that is held by the trunk 1 in the freely turnable manner with the handlebar 2; a rear wheel 4 that is held by the trunk 1 in a freely rotatable manner; a hydraulic pressure control unit 5; and a notification device 6. The hydraulic pressure control unit 5 is used for the brake system 10 of the vehicle 100. The notification device 6 notifies the rider. The notification device 6 has a sound output function and a display function. The sound output function is a function to output sound and is implemented by a speaker, for example. The display function is a function to show information visually, and is implemented by a liquid-crystal display, a lamp, or the like, for example. The vehicle 100 includes a drive source such as an engine or a motor, and travels by using power that is output from the drive source.

As illustrated in FIG. 1 and FIG. 2, the brake system 10 includes: a first brake operation section 11; the front-wheel brake mechanism 12 that brakes the front wheel 3 in an interlocking manner with at least the first brake operation section 11; a second brake operation section 13; and the rear-wheel brake mechanism 14 that brakes the rear wheel 4 in an interlocking manner with at least the second brake operation section 13. The brake system 10 also includes the hydraulic pressure control unit 5, and the front-wheel brake mechanism 12 and the rear-wheel brake mechanism 14 are partially included in the hydraulic pressure control unit 5. The hydraulic pressure control unit 5 is a unit that has a function of controlling a braking force to be applied to the front wheel 3 by the front-wheel brake mechanism 12 and a braking force to be applied to the rear wheel 4 by the rear-wheel brake mechanism 14.

The first brake operation section 11 is provided to the handlebar 2 and is operated by the rider's hand. The first brake operation section 11 is a brake lever, for example. The second brake operation section 13 is provided to a lower portion of the trunk 1 and is operated by the rider's foot. The second brake operation section 13 is a brake pedal, for example. However, like a brake operation section of the scooter or the like, each of the first brake operation section 11 and the second brake operation section 13 may be the brake lever that is operated by the rider's hand.

Each of the front-wheel brake mechanism 12 and the rear-wheel brake mechanism 14 includes: a master cylinder 21 in which a piston (not illustrated) is installed; a reservoir 22 that is attached to the master cylinder 21; a brake caliper 23 that is held by the trunk 1 and has a brake pad (not illustrated); a wheel cylinder 24 that is provided to the brake caliper 23; a primary channel 25 through which a brake fluid in the master cylinder 21 flows into the wheel cylinder 24; a secondary channel 26 through which the brake fluid in the wheel cylinder 24 is released; and a supply channel 27 through which the brake fluid in the master cylinder 21 is supplied to the secondary channel 26.

Each of the front-wheel brake mechanism 12 and the rear-wheel brake mechanism 14 is provided with an electromagnetic valve 31 for controlling a hydraulic pressure generated in the brake fluid as a hydraulic fluid. In an example illustrated in FIG. 2, the electromagnetic valves 31 are an inlet valve (EV) 31a, an outlet valve (AV) 31b, a first valve (USV) 31c, and a second valve (HSV) 31d.

The inlet valve 31a is provided to the primary channel 25. The secondary channel 26 bypasses a portion of the primary channel 25 between the wheel cylinder 24 side and the master cylinder 21 side of the inlet valve 31a. The secondary channel 26 is sequentially provided with the outlet valve 31b, an accumulator 32, and a pump 33 from an upstream side. The first valve 31c is provided between an end on the master cylinder 21 side of the primary channel 25 and a portion of the primary channel 25 to which a downstream end of the secondary channel 26 is connected. The supply channel 27 communicates between the master cylinder 21 and a portion on a suction side of the pump 33 in the secondary channel 26. The second valve 31d is provided to the supply channel 27.

The inlet valve 31a is the electromagnetic valve 31 that is opened in an unenergized state and is closed in an energized state, for example. The outlet valve 31b is the electromagnetic valve 31 that is closed in the unenergized state and opened in the energized state, for example. The first valve 31c is the electromagnetic valve 31 that is opened in the unenergized state and is closed in the energized state, for example. The second valve 31d is the electromagnetic valve 31 that is closed in the unenergized state and is opened in the energized state, for example.

The hydraulic pressure control unit 5 includes: a hydraulic pressure control mechanism 51 that includes a part of the front-wheel brake mechanism 12 and a part of the rear-wheel brake mechanism 14 described above; and a controller (ECU) 52 that controls operation of the hydraulic pressure control mechanism 51.

The hydraulic pressure control mechanism 51 includes: a base body 51a; and components that are assembled to the base body 51a and include the electromagnetic valves 31 for controlling the hydraulic pressure generated in the brake fluid as the hydraulic fluid in the brake system 10. The component means an element such as a part that is assembled to the base body 51a.

The base body 51a has a substantially rectangular-parallelepiped shape and is formed of a metal material, for example. In the base body 51a of the hydraulic pressure control mechanism 51, the primary channels 25, the secondary channels 26, and the supply channels 27 are formed, and the electromagnetic valves 31 (more specifically, the inlet valves 31a, the outlet valves 31b, the first valves 31c, and the second valves 31d), the accumulators 32, and the pumps 33 are assembled as the components. As will be described below, operation of each of these components is controlled by the controller 52 of the hydraulic pressure control unit 5. The base body 51a may be formed of one member or may be formed of plural members. In the case where the base body 51a is formed of the plural members, the components may separately be provided in the plural members.

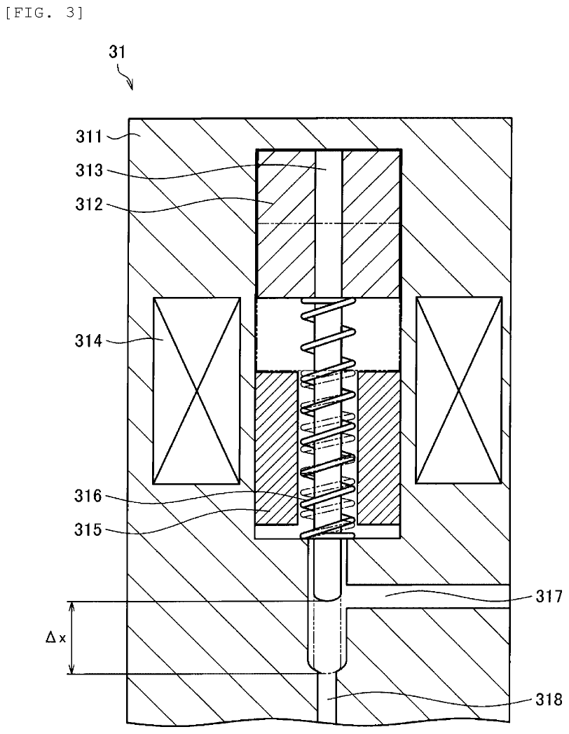

A description will hereinafter be made on a detailed configuration of the electromagnetic valve 31 that is provided to the hydraulic pressure control unit 5 with reference to FIG. 3. FIG. 3 is a schematic cross-sectional view illustrating an example of the electromagnetic valve 31 in the hydraulic pressure control unit 5. Hereinafter, a description will primarily be made on a case where the electromagnetic valve 31 in FIG. 3 is the valve that is closed in the energized state (more specifically, the inlet valve 31a and the first valve 31c). Then, a description on a case where the electromagnetic valve 31 is the valve that is opened in the energized state (more specifically, the outlet valve 31b and the second valve 31d) will be supplemented.

As illustrated in FIG. 3, the electromagnetic valve 31 includes a case 311, an armature 312, a tappet 313, a wire 314, a core 315, a spring 316, a first channel 317, and a second channel 318, for example.

The armature 312 corresponds to a movable portion that can reciprocate relative to the case 311 in the case 311. The armature 312 has a substantially cylindrical shape, for example. The armature 312 is arranged in an internal space that is formed on the inside of the case 311, and can reciprocate along an axial direction of the armature 312. The tappet 313 is fixed to the armature 312 and can move integrally with the armature 312. For example, the tappet 313 is a solid rod member that has a circular cross-sectional shape, and is fitted and fixed to an inner circumferential portion of the armature 312.

The wire 314 is fixed to the case 311, and generates a magnetic field when being applied with a current. For example, the wire 314 is provided in a manner to surround the internal space of the case 311 along a circumferential direction of the armature 312. The core 315 is an iron core that is magnetized by the magnetic field generated by the wire 314, and has a substantially cylindrical shape, for example. In the internal space of the case 311, the core 315 is coaxially arranged with the armature 312, and the tappet 313 is inserted through an inner circumferential portion of the core 315. When the core 315 is magnetized, a magnetic force in a direction to approach the core 315 acts on the armature 312. In this way, the armature 312 moves in association with application of the current to the wire 314.

The spring 316 urges the armature 312 in a direction away from the core 315. For example, in the internal space of the case 311, the spring 316 is provided in a manner to be held between an inner circumferential portion of the case 311 and an end surface on the core 315 side of the armature 312.

The first channel 317 and the second channel 318 are formed in the case 311 and each form a part of the primary channel 25, the secondary channel 26, or the supply channel 27 provided with the electromagnetic valve 31. In addition, in the case 311, the first channel 317 and the second channel 318 are mutually connected via a space in which a tip of the tappet 313 is accommodated.

In the electromagnetic valve 31 (more specifically, the inlet valve 31a and the first valve 31c) that is closed in the energized state, in a state where the current is not applied to the wire 314 (that is, the unenergized state), as indicated by solid lines in FIG. 3, the armature 312 is held at a separated position from the core 315 by an urging force of the spring 316. In this way, the first channel 317 and the second channel 318 are brought into a mutually communicating state (that is, a state where the electromagnetic valve 31 is opened).

Meanwhile, in a state where the current is applied to the wire 314 (that is, in the energized state), the armature 312 is attracted with the tappet 313 to the core 315 side by the magnetic force that is generated between the armature 312 and the magnetized core 315, and is thereby held at a position indicated by two-dot chain lines in FIG. 3. In this way, an opening at an end of the second channel 318 is closed by the tip of the tappet 313. As a result, the first channel 317 and the second channel 318 are brought into a mutually blocked state (that is, a state where the electromagnetic valve 31 is closed).

In the electromagnetic valve 31 that is opened in the energized state (more specifically, each of the outlet valve 31b and the second valve 31d), in the unenergized state, as indicated by the two-dot chain lines in FIG. 3, the opening at the end of the second channel 318 is closed by the tip of the tappet 313, and the first channel 317 and the second channel 318 are brought into the mutually blocked state (that is, the state where the electromagnetic valve 31 is closed). Then, in the energized state, the magnetic force in a direction away from the opening at the end of the second channel 318 acts on the armature 312, and, as indicated by the solid lines in FIG. 3, the first channel 317 and the second channel 318 are brought into the mutually communicating state (that is, the state where the electromagnetic valve 31 is opened).

As illustrated in FIG. 2, the hydraulic pressure control unit 5 is provided with a current sensor 41 that detects a current value of the current flowing through the wire 314 of the electromagnetic valve 31. Here, the current sensor 41 may detect another physical quantity that can substantially be converted to the current value of the current flowing through the wire 314 of the electromagnetic valve 31. The current sensor 41 is provided for each of the electromagnetic valves 31. More specifically, the current sensors 41 are: a current sensor 41a that is provided for the inlet valve 31a; a current sensor 41b that is provided for the outlet valve 31b, a current sensor 41c that is provided for the first valve 31c; and a current sensor 41d that is provided for the second valve 31d. A detection result of each of the current sensors 41 is output to the controller 52 and used for processing executed by the controller 52.

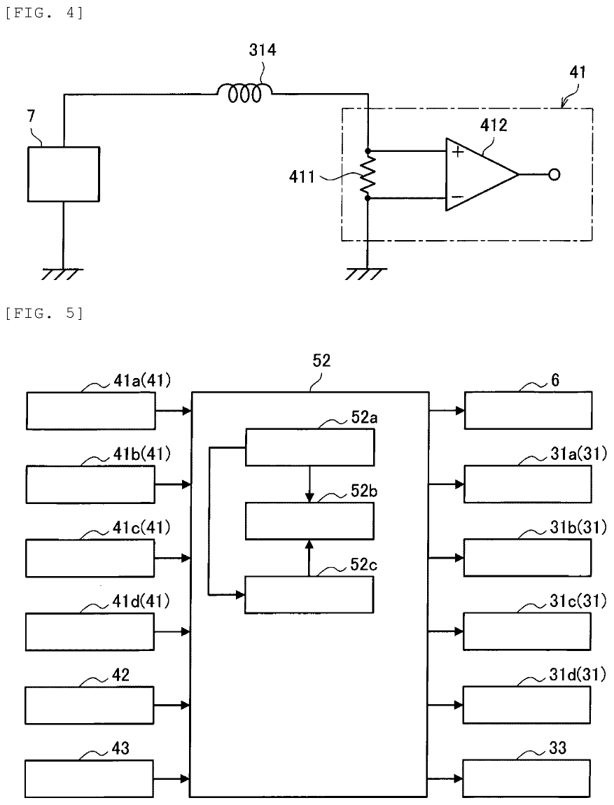

A detailed description will hereinafter be made on the current sensor 41 that is provided to the hydraulic pressure control unit 5 with reference to FIG. 4. FIG. 4 is a schematic view illustrating an example of the current sensor 41 in the hydraulic pressure control unit 5.

As illustrated in FIG. 4, the current sensor 41 includes a shunt resistor 411 and an operational amplifier 412, for example.

The shunt resistor 411 is connected in series with the wire 314 of the electromagnetic valve 31 that is connected to a power supply 7 such as a secondary battery. Electric power is supplied from the power supply 7 to the wire 314 of the electromagnetic valve 31. The operational amplifier 412 is connected in parallel with the shunt resistor 411, and amplifies and outputs a voltage difference between both ends of the shunt resistor 411. The current sensor 41 detects the current value of the current flowing through the wire 314 of the electromagnetic valve 31 on the basis of a resistance value of the shunt resistor 411 and an output value of the operational amplifier 412.

As illustrated in FIG. 2, the hydraulic pressure control unit 5 is provided with temperature sensors 42, 43, each of which detects a temperature of the brake fluid. Each of the temperature sensors 42, 43 may detect another physical quantity that can substantially be converted to the temperature of the brake fluid. The temperature sensor 42 is provided to the front-wheel brake mechanism 12 and detects the temperature of the brake fluid in the front-wheel brake mechanism 12. The temperature sensor 43 is provided to the rear-wheel brake mechanism 14 and detects the temperature of the brake fluid in the rear-wheel brake mechanism 14. Each of the temperature sensors 42, 43 is provided in a master cylinder pressure sensor, for example.

The controller 52 of the hydraulic pressure control unit 5 controls the operation of the above-described components that are assembled to the base body 51a of the hydraulic pressure control mechanism 51. For example, the controller 52 is partially or entirely constructed of a microcomputer, a microprocessor unit, or the like. In addition, the controller 52 may partially or entirely be constructed of one whose firmware and the like can be updated, or may partially or entirely be a program module or the like that is executed by a command from a CPU or the like, for example. The controller 52 may be provided as one unit or may be divided into plural units, for example. In addition, the controller 52 may be attached to the base body 51a or may be attached to a member other than the base body 51a.

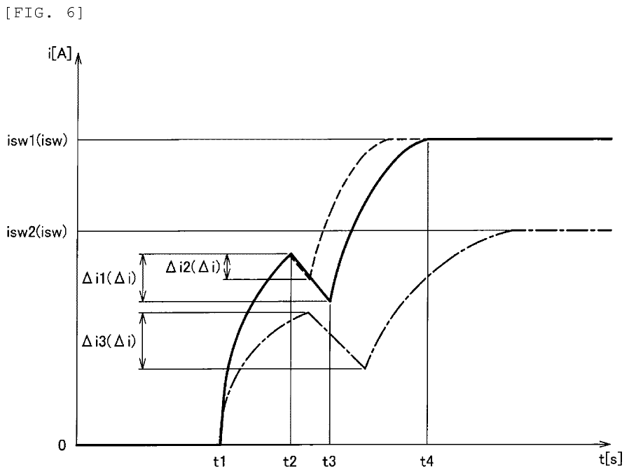

FIG. 5 is a block diagram illustrating an example of a functional configuration of the controller 52 in the hydraulic pressure control unit 5. As illustrated in FIG. 5, the controller 52 includes an acquisition section 52a, a control section 52b, and an evaluation section 52c, for example.

The acquisition section 52a acquires information from each of the sensors provided to the hydraulic pressure control unit 5 and outputs the acquired information to the control section 52b and the evaluation section 52c. For example, the acquisition section 52a acquires information from each of the current sensors 41 and the temperature sensors 42, 43.

The control section 52b controls the operation of each of the above-described components that are assembled to the base body 51a of the hydraulic pressure control mechanism 51. In this way, the control section 52b can control the braking force to be applied to the front wheel 3 by the front-wheel brake mechanism 12 and the braking force to be applied to the rear wheel 4 by the rear-wheel brake mechanism 14. As will be described below, the control section 52b can also control operation of the notification device 6.

The control section 52b controls the operation of each of the above components according to a travel state of the vehicle 100, for example. In a normal time (that is, when anti-lock brake control, automated brake control, or the like, which will be described below, is not executed), the control section 52b opens the inlet valve 31a and closes the outlet valve 31b. When the first brake operation section 11 is operated in such a state, in the front-wheel brake mechanism 12, the piston (not illustrated) in the master cylinder 21 is pressed to increase the hydraulic pressure of the brake fluid in the wheel cylinder 24, the brake pad (not illustrated) of the brake caliper 23 is then pressed against a rotor 3a of the front wheel 3, and the braking force is thereby generated on the front wheel 3. Meanwhile, when the second brake operation section 13 is operated, in the rear-wheel brake mechanism 14, the piston (not illustrated) in the master cylinder 21 is pressed to increase the hydraulic pressure of the brake fluid in the wheel cylinder 24, the brake pad (not illustrated) of the brake caliper 23 is then pressed against a rotor 4a of the rear wheel 4, and the braking force is thereby generated on the rear wheel 4.

The anti-lock brake control is control that is executed when the wheel (more specifically, the front wheel 3 or the rear wheel 4) is locked or possibly locked and that reduces the braking force to be applied to the wheel without relying on a brake operation by the rider, for example. For example, when the anti-lock brake control is executed, the control section 52b closes the inlet valve 31a, opens the outlet valve 31b, opens the first valve 31c, and closes the second valve 31d. When the pump 33 is driven by the control section 52b in such a state, the hydraulic pressure of the brake fluid in the wheel cylinder 24 is reduced, and the braking force that is applied to the wheel is thereby reduced.

The automated brake control is control that is executed when it is necessary to stabilize a posture of the vehicle 100 during turning or the like of the vehicle 100 and that causes generation of the braking force to be applied to the wheel (more specifically, the front wheel 3 or the rear wheel 4) without relying on the brake operation by the rider, for example. For example, when the automated brake control is executed, the control section 52b opens the inlet valve 31a, closes the outlet valve 31b, closes the first valve 31c, and opens the second valve 31d. When the pump 33 is driven by the control section 52b in such a state, the hydraulic pressure of the brake fluid in the wheel cylinder 24 is increased, and the braking force that brakes the wheel is thereby generated.

The evaluation section 52c evaluates viscosity of the brake fluid as the hydraulic fluid in the brake system 10. In the evaluation of the viscosity of the brake fluid, the evaluation section 52c may specifically specify an estimation value of the viscosity of the brake fluid or may roughly specify a degree of the viscosity of the brake fluid.

Here, the viscosity of the hydraulic fluid such as the brake fluid is changed as the hydraulic fluid is deteriorated. For example, there is a case where the brake fluid absorbs moisture in atmospheric air in the course of use thereof. In addition, for example, water may directly enter into the brake fluid during replacement of the brake fluid, or the like. As a result of an increase in water content of the brake fluid due to any of these factors, the brake fluid is deteriorated. When the brake fluid is deteriorated and the water content of the brake fluid is increased, the viscosity of the brake fluid is increased. When the viscosity of the brake fluid is increased, movement of the armature 312 of the electromagnetic valve 31 tends to be restricted.

In the example illustrated in FIG. 3, when the current is applied to the wire 314, as indicated by the two-dot chain lines in FIG. 3, the armature 312 moves to a position at which the electromagnetic valve 31 is brought into the closed state. That is, a stroke amount Δx (see FIG. 3) of the armature 312 is large enough to cause the electromagnetic valve 31 to function appropriately. The stroke amount Δx of the armature 312 is a distance from a movement start position to a movement end position of the armature 312 (that is, an movement amount of the armature 312) when the current is applied to the wire 314 of the electromagnetic valve 31. As described above, since the tappet 313 can move integrally with the armature 312, the stroke amount Δx of the armature 312 matches a stroke amount of the tappet 313. In the case where the viscosity of the brake fluid is increased, the stroke amount Δx of the armature 312 is reduced, which possibly hinders the brake fluid from being blocked or distributed by the electromagnetic valve 31 as expected. Here, in the case where the viscosity of the brake fluid is increased, a moving speed of the armature 312 is also reduced. This can also be a factor that inhibits the brake fluid from being blocked or distributed by the electromagnetic valve 31 as expected. To handle such problems, in order to comprehend an actuation state of the electromagnetic valve 31 (that is, whether the electromagnetic valve 31 is in an appropriate functioning state), it is necessary to evaluate the viscosity of the brake fluid.

In this embodiment, the viscosity of the brake fluid is accurately evaluated by devising processing related to the evaluation of the viscosity of the brake fluid that is executed by the controller 52. A detailed description on such processing related to the evaluation of the viscosity of the brake fluid will be made below.

### Operation of Hydraulic Pressure Control Unit

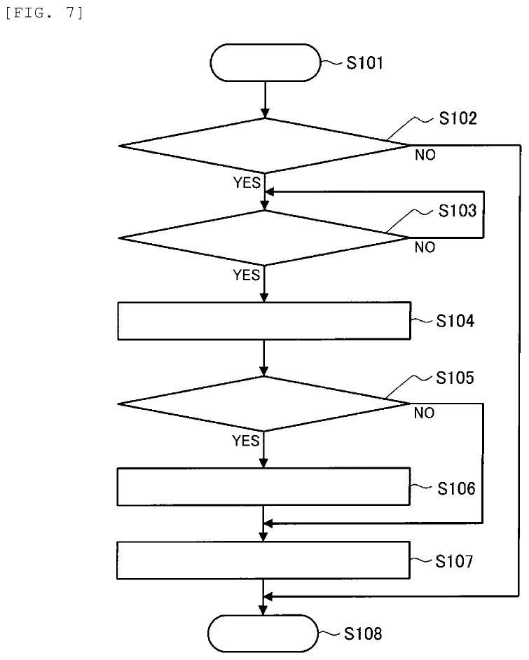

A description will herein be made on operation of the hydraulic pressure control unit 5 according to the embodiment of the present invention with reference to FIG. 6 and FIG. 7.

In this embodiment, the evaluation section 52c evaluates the viscosity of the brake fluid on the basis of behavior of the current value of the current flowing through the wire 314 at beginning of the application of the current to the wire 314 of the electromagnetic valve 31. A description will hereinafter be made on the behavior of the current value of the current flowing through the wire 314 at the beginning of the application of the current to the wire 314 with reference to FIG. 6.

FIG. 6 is a schematic graph illustrating an example of transition of the current value of the current flowing through the wire 314 at the beginning of the application of the current to the wire 314 of the electromagnetic valve 31 in the hydraulic pressure control unit 5. In FIG. 6, a horizontal axis represents time t[s], and a vertical axis represents a current value i[A] of the current flowing through the wire 314.

When the current starts being applied to the wire 314 of the electromagnetic valve 31, the current value i of the current flowing through the wire 314 starts being increased toward a target current value isw. Then, after reaching the target current value isw, the current value i is maintained at the target current value isw. In the present specification, the beginning of the application of the current to the wire 314 of the electromagnetic valve 31 means a period from time at which the current value i starts being increased in association with the application of the current to the wire 314 to time at which the current value i reaches the target current value isw.

In an example indicated by a solid line in FIG. 6, at a time point t1, the current starts being applied to the wire 314, and the current value i of the current flowing through the wire 314 starts being increased. Thereafter, at a time point t4, the current value i reaches a target current value isw1. Then, at the time point t4 onward, the current value i is maintained at the target current value isw1. The target current value isw in the example indicated by the solid line in FIG. 6 is the target current value isw1. However, the control section 52b can vary the target current value isw.

Here, when the current starts being applied to the wire 314, the core 315 is magnetized, and the magnetic force in the direction to approach the core 315 acts on the armature 312. Consequently, the armature 312 is attracted to and moves toward the core 315 side with the tappet 313. At this time, in the magnetic field generated by the wire 314, the armature 312 moves relative to the magnetic field. As a result, a counter-electromotive force is generated to the wire 314 in a manner to weaken magnetic flux generated by the wire 314. Thus, in a process in which the current value i of the current flowing through the wire 314 is increased toward the target current value isw, the current value i exhibits behavior of being temporarily reduced. For example, in the example indicated by the solid line in FIG. 6, at a time point t2, the current value i starts being reduced. Thereafter, at a time point t3, the reduction of the current value i is stopped, and the current value i starts being increased again toward the target current value isw.

In this embodiment, the evaluation section 52c evaluates the viscosity of the brake fluid on the basis of a reduced amount Δi of the current value i at the time when the current value i of the current flowing through the wire 314 is temporarily reduced in the process in which the current value i is increased toward the target current value isw at the beginning of the application of the current to the wire 314 of the electromagnetic valve 31. For example, the reduced amount Δi in the example indicated by the solid line in FIG. 6 is a reduced amount Δi1 that corresponds to a difference between the current value i at the time point t2 and the current value i at the time point t3. When a phenomenon that the counter-electromotive force is generated to the wire 314 in association with the movement of the armature 312 is focused, it is understood that, as the viscosity of the brake fluid is increased, the stroke amount Δx of the armature 312 is reduced, and the reduced amount Δi of the current value i is reduced. Here, as the viscosity of the brake fluid is increased, the moving speed of the armature 312 is reduced.

This can also be a factor that reduces the reduced amount Δi of the current value i. Accordingly, the evaluation section 52c evaluates that the viscosity of the brake fluid is high as the reduced amount Δi is reduced, for example. Just as described, by focusing on the phenomenon that the counter-electromotive force is generated to the wire 314 in association with the movement of the armature 312, it is possible to evaluate the viscosity of the brake fluid while taking the change in the viscosity associated with the deterioration of the hydraulic fluid into account. Therefore, it is possible to accurately evaluate the viscosity of the brake fluid.

Here, the evaluation section 52c determines that the current value i is temporarily reduced in the case where the current value i at a time point after a lapse of a reference period from the reduction start time point of the current value i (for example, the time point t2 in the example indicated by the solid line in FIG. 6) is lower by a reference value or more than the current value i at the reduction start time point (that is, in the case where a difference between the current value i at the time point after the lapse of the reference period from the reduction start time point of the current value i and the current value i at the reduction start time point is equal to or larger than the reference value). Each of the reference period and the reference value described above is set to a value with which it is possible to distinguish whether the current value i is temporarily reduced due to the generation of the counter-electromotive force to the wire 314 or a detection value of the current sensor 41 is only momentarily and slightly reduced by a noise component. That is, in the case where the difference between the current value i at the time point after the lapse of the reference period from the reduction start time point of the current value i and the current value i at the reduction start time point is smaller than the reference value, the evaluation section 52c determines that the detection value of the current sensor 41 is only momentarily and slightly reduced by the noise component, and thus does not evaluate the viscosity of the brake fluid.

Here, compared to the example indicated by the solid line, an example indicated by a broken line in FIG. 6 is an example at the different brake fluid temperature. In addition, compared to the example indicated by the solid line, an example indicated by a one-dot chain line in FIG. 6 is an example with the different target current value isw. These examples will be described below.

FIG. 7 is a flowchart illustrating an example of a processing procedure related to the evaluation of the viscosity of the brake fluid that is executed by the controller 52 in the hydraulic pressure control unit 5. For example, the control flow illustrated in FIG. 7 is repeatedly initiated at a time interval, which is set in advance, after being terminated. Step S101 and step S108 in FIG. 7 respectively correspond to initiation and termination of the control flow.

In the control flow illustrated in FIG. 7, as described above, the evaluation section 52c evaluates the viscosity of the brake fluid on the basis of the behavior of the current value i of the current flowing through the wire 314 of the electromagnetic valve 31. Here, in the case where the evaluation section 52c evaluates the viscosity of the brake fluid in the front-wheel brake mechanism 12, the evaluation section 52c evaluates the viscosity of the brake fluid on the basis of the behavior of the current value i of the current flowing through the wire 314 of the electromagnetic valve 31 in the front-wheel brake mechanism 12. Meanwhile, in the case where the evaluation section 52c evaluates the viscosity of the brake fluid in the rear-wheel brake mechanism 14, the evaluation section 52c evaluates the viscosity of the brake fluid on the basis of the behavior of the current value i of the current flowing through the wire 314 of the electromagnetic valve 31 in the rear-wheel brake mechanism 14. The processing related to the evaluation of the viscosity of the brake fluid, which will be described below, may be executed on the basis of the behavior of the current value i of the valve that is closed in the energized state (more specifically, the inlet valve 31a and the first valve 31c), or may be executed on the basis of the behavior of the current value i of the valve that is opened in the energized state (more specifically, the outlet valve 31b and the second valve 31d).

When the control flow illustrated in FIG. 7 is initiated, in step S102, the evaluation section 52c determines whether the current starts being applied to the wire 314 of the electromagnetic valve 31. If it is determined that the current starts being applied to the wire 314 (step S102/YES), the processing proceeds to step S103. On the other hand, if it is determined that the current does not start being applied to the wire 314 (step S102/NO), the control flow illustrated in FIG. 7 is terminated.

For example, the evaluation section 52c determines whether the current starts being applied to the wire 314 on the basis of the detection value of the current sensor 41. As described above, when the current starts being applied to the wire 314, the current value i of the current flowing through the wire 314 starts being increased toward the target current value isw. Accordingly, the evaluation section 52c can determine whether the current starts being applied to the wire 314 on the basis of the behavior of the current value i of the current flowing through the wire 314 (for example, whether the current value i is increased to exceed a specified value).

If it is determined YES in step S102, in step S103, the evaluation section 52c determines whether the current value i of the current flowing through the wire 314 of the electromagnetic valve 31 stops being increased. If it is determined that the current value i of the current flowing through the wire 314 stops being increased (step S103/YES), the processing proceeds to step S104. On the other hand, if it is determined that the current value i of the current flowing through the wire 314 does not stop being increased (step S103/NO), the determination processing in step S103 is repeated.

For example, the evaluation section 52c determines whether the current value i of the current flowing through the wire 314 stops being increased on the basis of the detection value of the current sensor 41. As described above, after being increased to the target current value isw, the current value i of the current flowing through the wire 314 is maintained at the target current value isw. Accordingly, the evaluation section 52c can determine whether the current value i of the current flowing through the wire 314 stops being increased on the basis of the behavior of the current value i of the current flowing through the wire 314 (for example, whether a fluctuation width of the current value i becomes equal to or smaller than a specified value).

If it is determined YES in step S103, in step S104, the evaluation section 52c evaluates the viscosity of the brake fluid. More specifically, as described above, the evaluation section 52c evaluates the viscosity of the brake fluid on the basis of the reduced amount Δi of the current value i at the time when the current value i of the current flowing through the wire 314 is temporarily reduced in the process in which the current value i is increased toward the target current value isw at the beginning of the application of the current to the wire 314 of the electromagnetic valve 31. For example, after step S102 and until it is determined YES in step S103, the acquisition section 52a keeps acquiring the current value i at each of the time points, and the evaluation section 52c can identify the reduced amount Δi on the basis of history of the acquired current value i.

Here, from a perspective of improving evaluation accuracy of the viscosity of the brake fluid, the evaluation section 52c preferably evaluates the viscosity of the brake fluid on the basis of another parameter in addition to the reduced amount Δi of the current value i.

For example, the evaluation section 52c evaluates the viscosity of the brake fluid on the basis of the temperature of the brake fluid in addition to the reduced amount Δi of the current value i. In the evaluation of the viscosity of the brake fluid in the front-wheel brake mechanism 12, the evaluation section 52c evaluates the viscosity of the brake fluid on the basis of the temperature of the brake fluid that is acquired from the temperature sensor 42, for example. Meanwhile, in the evaluation of the viscosity of the brake fluid in the rear-wheel brake mechanism 14, the evaluation section 52c evaluates the viscosity of the brake fluid on the basis of the temperature of the brake fluid that is acquired from the temperature sensor 43, for example.

Here, such a relationship is established that the viscosity of the brake fluid is increased as the temperature of the brake fluid is reduced. Compared to the example indicated by the solid line, in the example indicated by the broken line in FIG. 6, the temperature of the brake fluid is low, and the viscosity of the brake fluid is high. Thus, compared to the example indicated by the solid line, in the example indicated by the broken line in FIG. 6, the reduced amount Δi of the current value I is small. More specifically, the reduced amount Δi in the example indicated by the broken line in FIG. 6 is a reduced amount Δi2 that is smaller than the reduced amount Δi1.

As described above, there is a tendency that the reduced amount Δi of the current value i is reduced as the temperature of the brake fluid is reduced. Just as described, the reduced amount Δi of the current value i varies with a change in the temperature of the brake fluid. Thus, when evaluating the viscosity of the brake fluid by taking the temperature of the brake fluid into account in addition to the reduced amount Δi, the evaluation section 52c can improve the evaluation accuracy of the viscosity of the brake fluid.

For example, the evaluation section 52c evaluates the viscosity of the brake fluid on the basis of the target current value isw in addition to the reduced amount Δi of the current value i.

Here, compared to the example indicated by the solid line, in the example indicated by the one-dot chain line in FIG. 6, the target current value isw is small. More specifically, the target current value isw in the example indicated by the one-dot chain line in FIG. 6 is the target current value isw2 that is lower than the target current value isw1. Accordingly, compared to the example indicated by the solid line, in the example indicated by the one-dot chain line in FIG. 6, the reduced amount Δi of the current value i is large. More specifically, the reduced amount Δi in the example indicated by the one-dot chain line in FIG. 6 is a reduced amount Δi3 that is larger than the reduced amount Δi1.

As described above, there is a tendency that the reduced amount Δi of the current value i is increased as the target current value isw is reduced. Just as described, the reduced amount Δi of the current value i varies with the change in the target current value isw. Thus, when evaluating the viscosity of the brake fluid by taking the target current value isw into account in addition to the reduced amount Δi, the evaluation section 52c can improve the evaluation accuracy of the viscosity of the brake fluid.

The above description has sequentially been made on the example in which, in addition to the reduced amount Δi of the current value i, the temperature of the brake fluid is used to evaluate the viscosity of the brake fluid and the example in which, in addition to the reduced amount Δi of the current value i, the target current value isw is used to evaluate the viscosity of the brake fluid. Here, from a perspective of further effectively improving the evaluation accuracy of the viscosity of the brake fluid, the evaluation section 52c preferably evaluates the viscosity of the brake fluid on the basis of both of the temperature of the brake fluid and the target current value isw in addition to the reduced amount Δi of the current value i. Here, in the case where the estimation value of the viscosity is specifically identified in the evaluation of the viscosity of the brake fluid, a relationship between the estimation value of the viscosity and each of the parameters (for example, the reduced amount Δi, the temperature of the brake fluid, and the target current value isw) may be defined, and a mathematical formula, a map, or the like that is used to identify the estimation value of the viscosity may be determined on the basis of a theoretical formula or may be determined on the basis of an experimental result.

Next, in step S105, the control section 52b determines whether the viscosity of the brake fluid is higher than reference viscosity. If it is determined that the viscosity of the brake fluid is higher than the reference viscosity (step S105/YES), the processing proceeds to step S106, and the control section 52b increases the target current value isw to be higher than the current value. Accordingly, in the process of repeating the control flow illustrated in FIG. 7, the target current value isw is gradually increased until the viscosity of the brake fluid becomes equal to or lower than the reference viscosity (that is, until it is determined NO in step S105). On the other hand, if it is determined that the viscosity of the brake fluid is equal to or lower than the reference viscosity (step S105/NO), the processing proceeds to step S107.

The reference viscosity in step S105 is a value that is set to a value with which it is possible to determine whether the viscosity is increased due to the deterioration of the brake fluid, and is set to be increased as the temperature is reduced. That is, if it is determined that the viscosity of the brake fluid is equal to or lower than the reference viscosity (that is, if it is determined NO in step S105), it can be determined that the brake fluid is not deteriorated or that a degree of the deterioration is minute and thus the electromagnetic valve 31 is in the appropriate functioning state.

On the other hand, if it is determined that the viscosity of the brake fluid is higher than the reference viscosity (that is, if it is determined YES in step S105), it is possible to determine that the viscosity is increased due to the deterioration of the brake fluid and the electromagnetic valve 31 is in a state of not appropriately functioning. More specifically, there is a case where, when the viscosity is increased due to the deterioration of the brake fluid, the stroke amount Δx becomes insufficient and the brake fluid is no longer blocked or distributed as expected. In such a case, the control section 52b increases the target current value isw to be higher than the current value. In this way, it is possible to eliminate a shortage of the stroke amount Δx and cause the electromagnetic valve 31 to function appropriately. As described above, from a perspective of avoiding the shortage of the stroke amount Δx, the control section 52b preferably controls the target current value isw on the basis of an evaluation result of the viscosity of the brake fluid.

If it is determined NO in step S105, or following step S106, in step S107, the control section 52b controls the notification operation on the basis of the evaluation result of the brake fluid, and then the control flow illustrated in FIG. 7 is terminated.

The notification operation is operation to notify the rider of various types of information. For example, the notification operation is performed by the notification device 6 and may be operation to show the information or operation to output the sound. Here, in the case where the notification operation continues for a set time, the control flow illustrated in FIG. 7 may be terminated. Alternatively, in the case where the rider performs an input operation to stop the notification operation, the control flow illustrated in FIG. 7 may be terminated.

In step S107, for example, if it is determined that the viscosity of the brake fluid is higher than the reference viscosity (that is, if it is determined YES in step S105), the control section 52b causes the notification device 6 to perform the notification operation so as to notify that the viscosity is increased due to the deterioration of the brake fluid. In this way, the rider can be urged to replace the brake fluid. On the other hand, if it is determined that the viscosity of the brake fluid is equal to or lower than the reference viscosity (that is, if it is determined NO in step S105), the control section 52b stops the notification operation by the notification device 6. However, if it is determined NO in step S105, the control section 52b may cause the notification device 6 to perform the notification operation to notify that the brake fluid is not deteriorated or that the degree of the deterioration is minute.

The notification operation may be performed by a device other than the notification device 6. For example, the notification operation may be performed by a display device (for example, a transmissive display arranged over the rider's line of sight) that is provided to a helmet worn on the rider's head. Alternatively, for example, the notification operation may be performed by a sound output device that is provided to the helmet worn on the rider's head. Further alternatively, for example, the notification operation may be operation to generate vibration by a vibration generator that is provided to the vehicle 100 or is attached to the rider. For example, the notification operation may be operation to instantaneously decelerate the vehicle 100. The above instantaneous deceleration may occur by reducing output of the drive source, may occur by generating the braking force by the hydraulic pressure control unit 5, or may occur by changing a gear ratio of a transmission mechanism of the vehicle 100.

The above description has been made on the example of the processing procedure related to the evaluation of the viscosity of the brake fluid with reference to FIG. 7. However, the processing procedure related to the evaluation of the viscosity of the brake fluid is not limited to the example of the flowchart in FIG. 7. For example, an additional step may be added to the flowchart in FIG. 7. For example, some of the steps (for example, step S105, step S106, and the like) in the flowchart in FIG. 7 may be omitted. For example, an order of some of the steps in the flowchart of FIG. 7 may be changed (for example, step S107 may be executed prior to step S105).

Although a case where the reduced amount Δi of the current value i is excessively small is not described above, in such a case, the evaluation section 52c may execute processing other than the processing that has been described above. For example, in the case where the reduced amount Δi of the current value i is smaller than the reference amount, the evaluation section 52c may evaluate the viscosity of the brake fluid after the temperature of the brake fluid is increased. The reference amount is set to a value that is small enough to be able to determine that the armature 312 has not moved at the beginning of the application of the current to the wire 314. That is, in the case where the reduced amount Δi of the current value i is smaller than the reference amount, it is possible to determine that the armature 312 has not moved at the beginning of the application of the current to the wire 314.

In the case where the reduced amount Δi of the current value i is smaller than the reference amount, the reduced amount Δi is excessively small. Thus, it is difficult to evaluate the viscosity of the brake fluid on the basis of the reduced amount Δi. In addition, such a possibility is also considered that the armature 312 does not move due to a factor other than the increase in the viscosity of the brake fluid. Thus, in such a case, the evaluation section 52c evaluates the viscosity of the brake fluid after the temperature of the brake fluid is increased and the viscosity of the brake fluid is thereby reduced. In this way, in the case where the factor that hinders the movement of the armature 312 is the increase in the viscosity of the brake fluid, the viscosity of the brake fluid can be evaluated by using the reduced amount Δi in a state where the reduced amount Δi becomes equal to or larger than the reference amount in association with the reduction in the viscosity of the brake fluid. Meanwhile, in the case where the factor that hinders the movement of the armature 312 is a factor other than the increase in the viscosity of the brake fluid, the reduced amount Δi is maintained in the state of being smaller than the reference amount. Thus, the above factor can be comprehended.

### Effects of Hydraulic Pressure Control Unit

A description will be made on effects of the hydraulic pressure control unit 5 according to the embodiment of the present invention.

In the hydraulic pressure control unit 5, the evaluation section 52c evaluates the viscosity of the brake fluid as the hydraulic fluid on the basis of the reduced amount Δi of the current value i at the time when the current value i of the current flowing through the wire 314 is temporarily reduced in the process in which the current value i is increased toward the target current value isw at the beginning of the application of the current to the wire 314 of the electromagnetic valve 31. In this way, by focusing on the phenomenon that the counter-electromotive force is generated to the wire 314 in association with the movement of the armature 312, it is possible to evaluate the viscosity of the brake fluid while taking the change in the viscosity associated with the deterioration of the hydraulic fluid into account. Therefore, it is possible to accurately evaluate the viscosity of the brake fluid.

Preferably, in the hydraulic pressure control unit 5, the evaluation section 52c evaluates the viscosity of the brake fluid on the basis of the temperature of the brake fluid in addition to the reduced amount Δi of the current value i. In this way, it is possible to further appropriately evaluate the viscosity of the brake fluid by focusing on the relationship between the temperature of the brake fluid and the reduced amount Δi. Therefore, it is possible to improve the evaluation accuracy of the viscosity of the brake fluid.

Preferably, in the hydraulic pressure control unit 5, the evaluation section 52c evaluates the viscosity of the brake fluid on the basis of the target current value isw in addition to the reduced amount Δi of the current value i. In this way, it is possible to appropriately evaluate the viscosity of the brake fluid by focusing on the relationship between the target current value isw and the reduced amount Δi. Therefore, it is possible to improve the evaluation accuracy of the viscosity of the brake fluid.

Preferably, in the hydraulic pressure control unit 5, the control section 52b controls the notification operation on the basis of the evaluation result of the viscosity of the brake fluid. In this way, it is possible to notify the rider of the information on the evaluation result of the viscosity of the brake fluid. Thus, the rider can understand whether the electromagnetic valve 31 is in the appropriate functioning state. Therefore, safety is improved. In addition, by notifying the rider of the deterioration of the brake fluid, the rider can be urged to replace the brake fluid.

Preferably, in the hydraulic pressure control unit 5, the control section 52b controls the target current value isw on the basis of the evaluation result of the viscosity of the brake fluid. In this way, in the case where the viscosity is increased due to the deterioration of the brake fluid and the electromagnetic valve 31 does not function appropriately, it is possible to avoid the shortage of the stroke amount Δx and cause the electromagnetic valve 31 to function appropriately.

Preferably, in the hydraulic pressure control unit 5, the control section 52b increases the target current value isw in the case where the viscosity of the brake fluid is higher than the reference viscosity. In this way, in the case where the viscosity is increased due to the deterioration of the brake fluid and the electromagnetic valve 31 does not function appropriately, it is possible to avoid the shortage of the stroke amount Δx and cause the electromagnetic valve 31 to function appropriately.

Preferably, in the hydraulic pressure control unit 5, in the case where the reduced amount Δi of the current value i is smaller than the reference amount, the evaluation section 52c evaluates the viscosity of the brake fluid after the temperature of the brake fluid is increased. In this way, in the case where the factor that hinders the movement of the armature 312 is the increase in the viscosity of the brake fluid, the viscosity of the brake fluid can be evaluated by using the reduced amount Δi in the state where the reduced amount Δi becomes equal to or larger than the reference amount in association with the reduction in the viscosity of the brake fluid. Meanwhile, in the case where the factor that hinders the movement of the armature 312 is the factor other than the increase in the viscosity of the brake fluid, the reduced amount Δi is maintained in the state of being smaller than the reference amount. Thus, the above factor can be comprehended.

Preferably, in the hydraulic pressure control unit 5, the evaluation section 52c determines that the current value i is temporarily reduced in the case where the current value i at the time point after the lapse of the reference period from the reduction start time point of the current value i is lower by the reference value or more than the current value i at the reduction start time point. In this way, it is possible to distinguish whether the current value i is temporarily reduced due to the generation of the counter-electromotive force to the wire 314 or the detection value of the current sensor 41 is only instantaneously and slightly reduced by the noise component. Thus, it is possible to appropriately evaluate the viscosity of the brake fluid by focusing on the phenomenon that the counter-electromotive force is generated to the wire 314 in association with the movement of the armature 312.

The present invention is not limited to the embodiment that has been described. For example, only a part of the embodiment may be implemented.

### Reference Signs List

1: Trunk
2: Handlebar
3: Front wheel
3a: Rotor
4: Rear wheel
4a: Rotor
5: Hydraulic pressure control unit
6: Notification device
7: Power supply
10: Brake system
11: First brake operation section
12: Front-wheel brake mechanism
13: Second brake operation section
14: Rear-wheel brake mechanism
21: Master cylinder
22: Reservoir
23: Brake caliper
24: Wheel cylinder
25: Primary channel
26: Secondary channel
27: Supply channel
31: Electromagnetic valve
31a: Inlet valve
31b: Outlet valve
31c: First valve
31d: Second valve
32: Accumulator
33: Pump
41: Current sensor
41a: Current sensor
41b: Current sensor
41c: Current sensor
41d: Current sensor
42: Temperature sensor
43: Temperature sensor
51: Hydraulic pressure control mechanism
51a: Base body
52: Controller
52a: Acquisition section
52b: Control section
52c: Evaluation section
100: Vehicle
311: Case
312: Armature
313: Tappet
314: Wire
315: Core
316: Spring
317: First channel
318: Second channel
411: Shunt resistor
412: Operational amplifier
i: Current value
isw: Target current value
isw1: Target current value
isw2: Target current value
Δi: Reduced amount
Δi1: Reduced amount
Δi2: Reduced amount
Δi3: Reduced amount
Δx: Stroke amount

1. A hydraulic pressure control unit (5) used for a behavior control system (10) of a vehicle (100), the hydraulic pressure control unit comprising:
a hydraulic pressure control mechanism (51) that includes: a base body (51a); and
components that include an electromagnetic valve (31) assembled to the base body (51a) for controlling a hydraulic pressure generated in a hydraulic fluid for the behavior control system (10); and
a controller (52) that includes a control section (52b) controlling operation of the components; wherein
the electromagnetic valve (31) includes a wire (314) and an armature (312) that moves in association with application of a current to the wire (314), and is a valve that is closed or a valve that is opened in an energized state where the current is applied to the wire (314),
the controller (52) includes an evaluation section (52c) that evaluates viscosity of the hydraulic fluid, and
the evaluation section (52c) evaluates the viscosity on the basis of a reduced amount (Δi) of a current value (i) of the current flowing through the wire (314) at a time when the current value (i) is temporarily reduced in a process in which the current value (i) is increased toward a target current value (isw) at beginning of the application of the current to the wire (314).

2. The hydraulic pressure control unit according to claim 1, wherein
the evaluation section (52c) evaluates the viscosity based on a temperature of the hydraulic fluid in addition to the reduced amount (Δi).

3. The hydraulic pressure control unit according to claim 1, wherein
the evaluation section (52c) evaluates the viscosity on the basis of the target current value (isw) in addition to the reduced amount (Δi).

4. The hydraulic pressure control unit according to claim 1, wherein
the control section (52b) controls notification operation on the basis of an evaluation result of the viscosity.

5. The hydraulic pressure control unit according to claim 1, wherein
the control section (52b) controls the target current value (isw) on the basis of an evaluation result of the viscosity.

6. The hydraulic pressure control unit according to claim 5, wherein
the control section (52b) increases the target current value (isw) in the case where the viscosity is higher than reference viscosity.

7. The hydraulic pressure control unit according to claim 1, wherein
in the case where the reduced amount (Δi) is smaller than a reference amount, the evaluation section (52c) evaluates the viscosity after a temperature of the hydraulic fluid is increased.

8. The hydraulic pressure control unit according to claim 1, wherein
the evaluation section (52c) determines that the current value (i) is temporarily reduced in the case where the current value (i) at a time point after a lapse of a reference period from a reduction start time point of the current value (i) is lower by a reference value or more than the current value (i) at the reduction start time point.

9. The hydraulic pressure control unit according to claim 1, wherein
the vehicle (100) is a motorcycle.
